(19) United States
(12) Patent Application Publication
(10) Pub. No.: US 2021/0025940 A1
(43) Pub. Date: Jan. 28, 2021

(54) Method And Apparatus For Testing Nonlinear Parameter of Motor

(71) Applicant: AAC Technologies Pte. Ltd., Singapore City (SG)

(72) Inventors: Zheng Xiang, Shenzhen (CN); Xuan Guo, Shenzhen (CN); Xiang Lu, Shenzhen (CN)

(21) Appl. No.: 16/995,746

(22) Filed: Aug. 17, 2020

Related U.S. Application Data
(63) Continuation of application No. PCT/CN2019/093887, filed on Jun. 28, 2019.

(51) Int. Cl. G01R 31/34; G01R 27/26; G01R 33/02; G01M 5/00

(52) U.S. Cl. CPC G01R 31/343; G01R 27/2611; H02N 2/02; G01M 5/0066; G01R 33/02

(57) ABSTRACT

A method and an apparatus for testing a nonlinear parameter of a motor are provided. The method includes exciting the motor to vibrate by an excitation signal; performing synchronous information acquisition on the vibrating motor to obtain a measured voltage value and a measured current value; acquiring an initial value of a linear parameter and an initial value of a nonlinear parameter of the motor; calculating a target value of the linear parameter of the motor according to the measured voltage value, the measured current value and the initial value of the linear parameter; performing adaptive filtering calculation according to the measured voltage value, the measured current value, the target value of the linear parameter and the initial value of the nonlinear parameter to obtain a target value of the nonlinear parameter of the motor. A terminal device and a computer-readable storage medium are also provided.

### CROSS REFERENCE TO RELATED APPLICATIONS

This non-provisional patent application is a continuation application of International Application PCT/CN2019/093887, filed on Jun. 28, 2019, the content of which is incorporated herein by reference.

### TECHNICAL FIELD

The present disclosure relates to micro-electro-mechanical systems technology and, in particular, to a method and an apparatus for testing a nonlinear parameter of a motor.

### BACKGROUND

As science and technology advance, people have an increasingly greater demand on the intelligence and diversity as well as rich sensation and human-machine interaction experience of electronic products. Touch sensation is an important part of human sensation, and a linear resonance actuator (LRA, also called a motor) is a key component for outputting touch sensation. Therefore, the motors are more and more commonly used in electronic devices such as smartphones, smart watches, and tablet computers. The accuracy and completeness of technical parameters of the motors are crucial to the accuracy of modeling, and are the most key factors which affect the motor performance.

At present, the most frequently used motor is a magnet array-type linear motor based on Lorentz force (i.e. electromagnetic force). Such motor features a conventional second-order linear system model and is particularly advantageous in aspects of parameter determination and system control. However, such motor applies only to weak vibration applications. When stronger vibration is needed, the motor that is based on Lorentz force alone is not applicable.

In related art, in order to obtain high vibration intensity, novel motors based on magnetic force or other acting forces have been gradually put into use. However, forces received by the motors based on magnetic force or other acting forces are nonlinear forces. If the traditional second-order linear model is still used, it may lead to a relatively large modeling error, thus affecting the accuracy of motor control and hence causing a failure to achieve desired effects.

### SUMMARY

Accordingly, the present disclosure is directed to a method and an apparatus for testing a nonlinear parameter of a motor which can solve the problem in the prior art that large errors generated during nonlinear modeling of the linear resonance actuator result in low control precision of the linear resonance actuator and failure to achieve desired effects.

In one independent aspect, a method for testing a nonlinear parameter of a motor includes exciting the motor to vibrate by an excitation signal; performing synchronous information acquisition on the vibrating motor to obtain a measured voltage value and a measured current value; acquiring an initial value of a linear parameter and an initial value of a nonlinear parameter of the motor; calculating a target value of the linear parameter of the motor according to the measured voltage value, the measured current value and the initial value of the linear parameter; performing adaptive filtering calculation according to the measured voltage value, the measured current value, the target value of the linear parameter and the initial value of the nonlinear parameter to obtain a target value of the nonlinear parameter of the motor.

In one embodiment, the step of performing the adaptive filtering calculation includes acquiring a system initial value which affects the nonlinear parameter; calculating an update value of the nonlinear parameter according to the measured voltage value, the measured current value, the target value of the linear parameter, the initial value of the nonlinear parameter and the system initial value; calculating a difference between the update value of the nonlinear parameter and the initial value of the nonlinear parameter, and when the difference is smaller than a predetermined threshold value, setting the update value of the nonlinear parameter as the target value of the nonlinear parameter; when the difference is not smaller than the predetermined threshold value, calculating a system update value according to the measured voltage value, the measured current value, the target value of the linear parameter, the update value of the nonlinear parameter and the system initial value, setting the system update value as the system initial value and the update value of the nonlinear parameter as the initial value of the nonlinear parameter, and returning back to the step of calculating the update value of the nonlinear parameter according to the measured voltage value, the measured current value, the target value of the linear parameter, the initial value of the nonlinear parameter and the system initial value.

In one embodiment, the step of calculating the update value of the nonlinear parameter includes calculating a displacement of a vibrator of the motor according to the measured voltage value, the measured current value and the initial value of the linear parameter; and calculating the update value of the nonlinear parameter according to the target value of the linear parameter, the displacement of the vibrator of the motor and the system initial value.

In one embodiment, the step of calculating the system update value includes calculating an error value according to the measured voltage value, the measured current value, the target value of the linear parameter and the update value of the nonlinear parameter; and calculating the system update value according to the error value and the system initial value.

In one embodiment, the step of calculating the error value includes substituting the measured voltage value, the measured current value and the initial value of the linear parameter into an electric equation for vibration of the motor to solve for a first speed; substituting the measured voltage value, the measured current value, the target value of the linear parameter and the initial value of the nonlinear parameter into a mechanical equation for vibration of the motor to solve for a second speed; and calculating the error value according to the first speed and the second speed.

In one embodiment, the step of calculating the target value of the linear parameter of the motor includes deriving a voltage-to-current transfer function according to the electric equation and the mechanical equations for the motor; substituting the measured voltage value and the initial value of the linear parameter into the transfer function to solve for a calculated current value; and performing data fitting on the measured current value and the calculated current value to obtain the target value of the linear parameter.

In one embodiment, the step of exciting the motor to vibrate by the excitation signal includes generating the excitation signal; performing filtering treatment on the excitation signal; and exciting the motor to vibrate by the excitation signal after the filtering treatment.

In another independent aspect, an apparatus for testing a nonlinear parameter of a motor includes an excitation module configured for exciting the motor to vibrate by an excitation signal; an acquisition module configured for performing synchronous information acquisition on the vibrating motor to obtain a measured voltage value and a measured current value; an obtaining module configured for acquiring an initial value of a linear parameter and an initial value of a nonlinear parameter of the motor; and a calculation module configured for calculating a target value of the linear parameter of the motor according to the measured voltage value, the measured current value and the initial value of the linear parameter, the calculation module further configured for performing adaptive filtering calculation according to the measured voltage value, the measured current value, the target value of the linear parameter and the initial value of the nonlinear parameter to obtain a target value of the nonlinear parameter of the motor.

In another independent aspect, a terminal device is provided which includes at least one processor, a memory in communication with the at least one processor, and a computer program stored on the memory. The computer program is executable by the at least one processor to implement a method for testing a nonlinear parameter of a motor. The method includes exciting the motor to vibrate by an excitation signal; performing synchronous information acquisition on the vibrating motor to obtain a measured voltage value and a measured current value; acquiring an initial value of a linear parameter and an initial value of a nonlinear parameter of the motor; calculating a target value of the linear parameter of the motor according to the measured voltage value, the measured current value and the initial value of the linear parameter; and performing adaptive filtering calculation according to the measured voltage value, the measured current value, the target value of the linear parameter and the initial value of the nonlinear parameter to obtain a target value of the nonlinear parameter of the motor.

In still another independent aspect, a computer readable storage medium is provided which has a computer program stored thereon. The computer program is executable by a processor to implement a method for testing a nonlinear parameter of a motor. The method includes exciting the motor to vibrate by an excitation signal; performing synchronous information acquisition on the vibrating motor to obtain a measured voltage value and a measured current value; acquiring an initial value of a linear parameter and an initial value of a nonlinear parameter of the motor; calculating a target value of the linear parameter of the motor according to the measured voltage value, the measured current value and the initial value of the linear parameter; and performing adaptive filtering calculation according to the measured voltage value, the measured current value, the target value of the linear parameter and the initial value of the nonlinear parameter to obtain a target value of the nonlinear parameter of the motor.

Embodiments of the present disclosure provide a method and an apparatus for testing a nonlinear parameter of a linear resonance actuator. The method includes: exciting the motor to vibrate by an excitation signal; performing synchronous information acquisition on the vibrating motor to obtain a measured voltage value and a measured current value; acquiring an initial value of a linear parameter and an initial value of a nonlinear parameter of the motor; calculating a target value of the linear parameter of the motor according to the measured voltage value, the measured current value and the initial value of the linear parameter; performing adaptive filtering calculation according to the measured voltage value, the measured current value, the target value of the linear parameter and the initial value of the nonlinear parameter to obtain a target value of the nonlinear parameter of the motor. Measurement of the nonlinear parameter of the motor allows for accurate control of the vibration of the motor using a nonlinear model, which enhances the control precision of the motor. Therefore, the method disclosed herein improves the performance of the motor, and solves the problems in the related art that large errors generated during nonlinear modeling of the motor can result in low precision of motor control and failure to achieve the desired effects.

Independent features and/or independent advantages of this disclosure may become apparent to those skilled in the art upon review of the detailed description, claims and drawings.

### BRIEF DESCRIPTION OF THE DRAWINGS

FIG. 1 is a flowchart of a method for testing a nonlinear parameter of a motor according to a first embodiment of the present disclosure;

FIG. 2 is a schematic diagram illustrating linear system modeling for the motor;

FIG. 3 is a flowchart of a method for testing a nonlinear parameter of a motor according to a second embodiment of the present disclosure;

FIG. 4 is a schematic view showing an apparatus for testing a nonlinear parameter of a motor according to a third embodiment of the present disclosure; and

FIG. 5 is a schematic view showing a terminal device according to a fourth embodiment of the present disclosure.

### DESCRIPTION OF THE EMBODIMENTS

The present disclosure will be described further below with reference to the accompanying drawings and embodiments.

In the event of a nonlinear motor, modeling the motor using a nonlinear model can avoid the problems associated with the use of a conventional second-order physical model. When the conventional second-order physical model is used for modeling the motor, it ignores the nonlinear characteristics of the motor, which may cause inaccurate modeling and hence affect the control precision of the motor. Acquiring nonlinear parameters of the motor is the premise of modeling the motor using the nonlinear model. In this regard, the present disclosure provides a method for testing a nonlinear parameter of a motor.

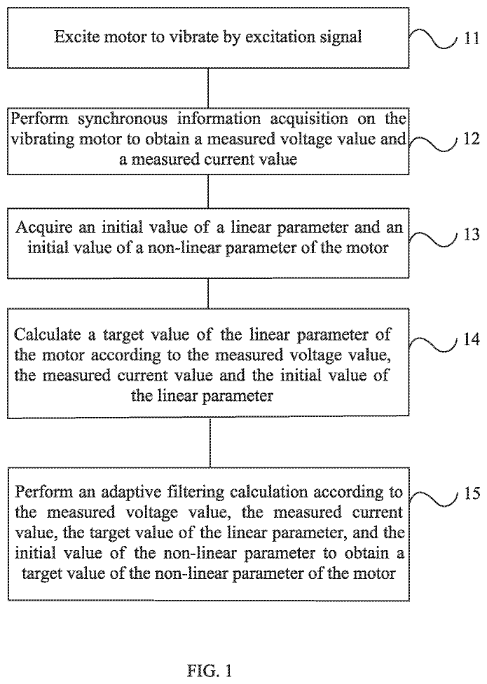

FIG. 1 is a flowchart of a method for testing a nonlinear parameter of a motor according to a first embodiment of the present disclosure. As shown in FIG. 1, the method for testing a nonlinear parameter of a motor according to this embodiment includes the following steps.

At Step 11, the motor is driven to vibrate by an excitation signal.

In this embodiment, the method is performed by an apparatus for testing a nonlinear parameter of a motor. The apparatus for testing a nonlinear parameter of a motor can be a testing apparatus, for example, a computer. The apparatus for testing a nonlinear parameter of a motor sends an excitation signal to the motor to drive the motor to start vibrating. Specifically, this step includes the following sub-steps.

At sub-step S111, an excitation signal is generated.

The apparatus for testing the nonlinear parameter of the motor generates the excitation signal upon test demands. Optionally, the excitation signal generated in this embodiment is a nonlinear test signal having a peak voltage smaller than a predetermined value, which can realize precise testing of the nonlinear parameter while avoiding damaging the motor due to the use of a large-amplitude test signal.

At sub-step S112, a filtering treatment is performed on the excitation signal.

For accurate modeling, the motor is driven at various displacements of a vibrator of the motor. In this embodiment, the generated excitation signal undergoes a filtering treatment to obtain an excitation signal with a certain bandwidth, and the excitation signal with a certain bandwidth is used to drive the motor. For example, the generated excitation signal is a full-bandwidth white noise, which is filtered using a band pass filter to obtain the excitation signal with a certain bandwidth.

At sub-step S113, the motor is driven to vibrate by the filtered excitation signal.

The filtered excitation signal is sent to a signal acquisition device connected to the motor. The signal acquisition device performs digital-to-analog conversion on the excitation signal to obtain an analog signal, and the analog signal is amplified with a power amplifier and then transmitted to the motor to drive the motor to vibrate.

Optionally, the signal acquisition device can be NI USB-4431, which is a five-channel USB type dynamic signal acquisition device for high-precision measurement of sound and vibration through an integrated circuit piezoelectric type sensor or a non-integrated circuit piezoelectric type sensor. It should be understood that the signal acquisition device described in this embodiment is for illustration only and can also be of other types in alternative embodiments.

At Step 12, synchronous information acquisition is performed on the motor that is vibrating to obtain a measured voltage value and a measured current value.

The apparatus for testing the nonlinear parameter of the motor acquires the voltage and current of the motor through the signal acquisition device.

Since the current in a series circuit is the same everywhere and is equal to the loop current, in order to facilitate acquisition of the current of the motor that is vibrating, a high-precision resistor is arranged between the power amplifier and the linear resonance actuator in this embodiment, and the current acquired from the high-precision resistor is thus the current of the motor. The current of the high-precision resistor can be acquired directly or indirectly through calculation of the voltage and resistance. In this embodiment, the current is acquired by indirect calculation. Specifically, the signal acquisition device acquires the voltage across two ends of the high-precision resistor; the resistance of the high-precision resistor is known (for example, a high-precision resistor with the resistance of 1Ω (ohm) is used); and the current is calculated with the voltage and the resistance.

The signal acquisition device acquires the voltage across two ends of the motor while acquiring the voltage across the two ends of the high-precision resistor. After obtaining the voltage and current of the motor, the signal acquisition device performs a digital-to analog conversion on the voltage and current so as to obtain the measured voltage value and the measured current value.

In this embodiment, components such as the power amplifier, signal amplifier and motor used for acquisition of the measured voltage value and the measured current value of the motor are not intended to be limited to any particular model.

At Step 13, an initial value of a linear parameter and an initial value of a nonlinear parameter of the motor are acquired.

Initial values of to-be-tested parameters of the motor include the initial value of the linear parameter and the initial value of the nonlinear parameter. The initial value of the linear parameter and the initial value of the nonlinear parameter can be initial values set at the factory, or can be pre-set by a user.

At Step 14, a target value of the linear parameter of the motor is calculated according to the measured voltage value, the measured current value and the initial value of the linear parameter.

The nonlinear model and the linear model of the motor are correlated. Therefore, to measure the nonlinear parameter of the motor, the linear parameter of the motor can be measured first. Calculating the target value of the linear parameter of the motor according to the measured voltage value, the measured current value and the initial value of the linear parameter specifically includes the following sub-steps.

At sub-step S141, a voltage-to-current transfer function is derived according to electric and mechanical equations for vibration of the motor.

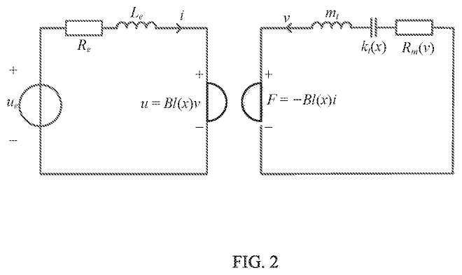

First, the electric equation and the mechanical equations for the motor are established according to the system characteristics of the motor as shown in FIG. 2.

Specifically, referring to the left part of the motor system as shown in FIG. 2, the electric equation is established in a time domain according to the voltage balance of an electric system of the motor, which obtains a formula (1):

$${u}_{e} ( t ) = {R}_{e} i ( t ) + {L}_{e} \frac{d i ( t )}{d t} + B l ( x ) v ( t ) \qquad ( 1 )$$

Referring to the right part of the motor system as shown in FIG. 2, the mechanical equation is established in a time domain according to torque balance of a mechanical system of the motor, which obtains a formula (2):

Bl(x)i(t)=mₜa(t)+Rₘ(x)v(t)+k(x)x(t) (2)

In the formulas (1) and (2), uₑ is the voltage across the two ends of the motor; Rₑ is the impedance of a voice coil of the motor; i is the current through the two ends of the motor; Lₑ is the inductance of the voice coil; Bl is the magnetic force coefficient; v is the speed of a vibrator of the motor; mₜ is a mass of the vibrator of the motor; a is the accelerator of the vibrator of the motor; Rₘ is the mechanical damping of a damper; kₜ is the suspension stiffness coefficient of a spring; x is the displacement of the vibrator of the motor; and t is time.

Then, the electric equation and the mechanical equation are transformed.

The electric equation (1) and the mechanical equation (2) are used to model the linear part of the motor system in the time domain. To perform analysis, the time domain needs to be transformed into a frequency domain. The transformation from the time domain to the frequency domain can be carried out by Fourier transform, Laplace transform and the like.

In this embodiment, Laplace transform is adopted for transformation from the time domain to the frequency domain. The electric equation (1) and the mechanical equation (2) are processed by Laplace transform to obtain a formula (3) and a formula (4), respectively:

uₑ(s)=Rₑi(s)+Lₑsi(s)+Blsx(s) (3)

Bli(s)=mₜs²x(s)+Rₘsx(s)+kₜx(s) (4)

In the formulas (3) and (4), s is frequency.

Finally, a voltage-to-current transfer function can be derived according to the transferred electrical equation and mechanical equations.

Specifically, formulas (3) and (4) are combined to eliminate x(s) so as to obtain a formula (5):

$$\frac{{u}_{e} ( s ) - {R}_{e} i ( s ) - {L}_{e} s i ( s )}{B l s} = \frac{B l i ( s )}{{m}_{t} {s}^{2} + {R}_{m} s + {k}_{t}} . \qquad ( 5 )$$

The formula (5) is transformed into the transfer function of the voltage uₑ to the current i of the motor, as shown in the formula (6):

$$\frac{i ( s )}{{u}_{e} ( s )} = \frac{{m}_{t} {s}^{2} + {R}_{m} s + {k}_{t}}{( {m}_{t} {s}^{2} + {R}_{m} s + {k}_{t} ) ( {R}_{e} + {L}_{e} s ) + B {l}^{2} s} . \qquad ( 6 )$$

In this model, the mechanical damping Rₘ of the damper, the stiffness coefficient kₜ of the spring, the impedance Rₑ of the voice coil of the linear resonance actuator, the inductance Lₑ of the voice coil, and the electromagnetic force coefficient Bl are measured linear parameters, and the vibrator mass mₜ of the motor is a constant.

At sub-step S142, the measured voltage value and the initial value of the linear parameter are inputted into the transfer function to solve for a calculated current value.

That is, the measured voltage value and the initial values of the linear parameters are substituted into formula (6) to obtain the calculated current value.

At sub-step S143, data fitting is performed on the measured current value and the calculated current value to obtain a target value of the linear parameter.

First, data fitting is performed on the measured current value and the calculated current value.

Optionally, in this embodiment, a least square method is adopted to perform data fitting on the measured current value and the calculated current value. The least square method is a mathematical optimization method which seeks the optimal test results of the tested parameters of the motor by minimizing the quadratic sum of errors. The least square method can easily solve for unknown data and minimize the quadratic sum of errors between the solved data and actual data. As an existing algorithm, the least square method can be directly used, and therefore is not described in detail in this embodiment. Certainly, other methods can also be used for data fitting, for example, a method of using an analytic expression to approximate discrete data can be used. This embodiment is not intended to use any particular data fitting method.

Second, it is judged whether or not the current fitting result meets a preset condition; and if yes, the current fitting result is determined as the target value of the linear parameter. If not, the initial value of the linear parameter is updated according to the current fitting result, the updated value of the linear parameter is used as a new initial value of the linear parameter, and the process returns to sub-step S142, i.e. substituting the measured voltage value and the initial value of the linear parameter into the transfer function to solve for a calculated current value is implemented again.

When the current fitting result meets the preset condition, it is determined that the current fitting result is the final fitting result to obtain the target value of the linear parameter. For example, the target values of the following linear parameters are obtained with the formula (6) by fitting: the mechanical damping Rₘ of the damper, the stiffness coefficient kₜ of the spring, the impedance Rₑ of the voice coil of the linear resonance actuator, the inductance Lₑ of the voice coil and the electromagnetic force coefficient Bl.

At Step 15, an adaptive filtering calculation is performed according to the measured voltage value, the measured current value, the target value of the linear parameter and the initial value of the nonlinear parameter to obtain a target value of the nonlinear parameter of the motor.

A calculation formula for the nonlinear parameter of the linear resonance actuator is established. The measured voltage value, the measured current value, the target value of the linear parameter and the initial value of the nonlinear parameter are substituted into the calculation formula, and the adaptive filtering calculation is performed to obtain the target value of the nonlinear parameter of the motor.

Adaptive filtering refers to automatically adjusting a filtering parameter at the current moment using the filtering parameter obtained at a previous moment to adapt to unknown or time-dependent statistical characteristics of signals and noises so as to realize optimal filtration. Frequently used adaptive filtering techniques include a least mean square (LMS) adaptive filter, a recursive least square (RLS) filter, a lattice filter, or an infinite impulse response (IIR) filter, etc.

This embodiment provides the method for testing the nonlinear parameter of the motor. The method includes the following steps of: exciting the motor to vibrate by an excitation signal; performing synchronous information acquisition on the vibrating motor to obtain the measured voltage value and the measured current value; acquiring the initial value of the linear parameter and the initial value of the nonlinear parameter of the motor; calculating the target value of the linear parameter of the motor according to the measured voltage value, the measured current value and the initial value of the linear parameter; and performing adaptive filtering calculation according to the measured voltage value, the measured current value, the target value of the linear parameter and the initial value of the nonlinear parameter to obtain the target value of the nonlinear parameter of the linear resonance actuator. Measurement of the nonlinear parameter of the motor allows for accurate control of the vibration of the motor using the nonlinear model, which enhances the accuracy of motor control. Therefore, the method disclosed herein improves the performance of the linear resonance actuator, and solves the problem in the related art that large errors generated during nonlinear modeling of the motor result in low accuracy of motor control and failure to achieve the desired effects.

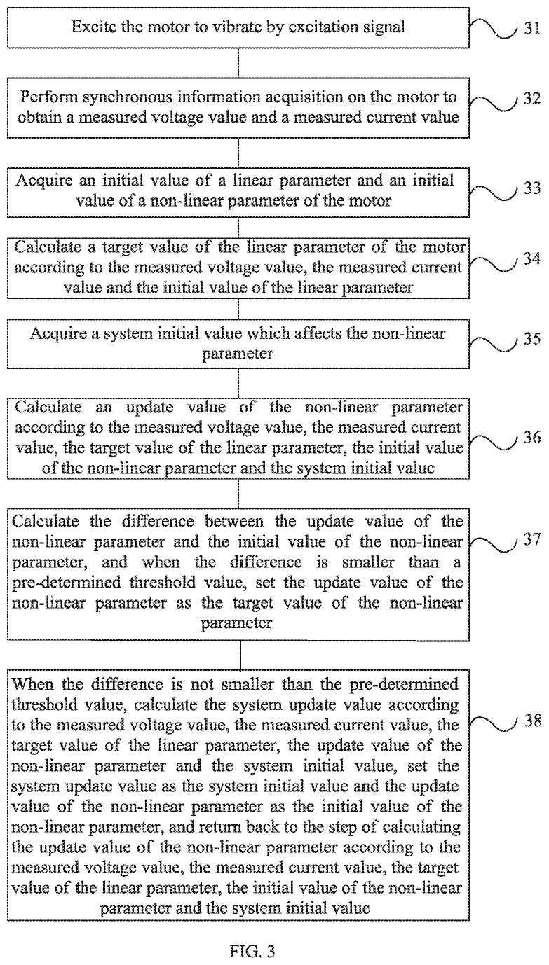

FIG. 3 is a flowchart of a method for testing a nonlinear parameter of a motor according to second embodiment 2 the present disclosure, and in particular relates to a possible implementation mode of step 15 in the first embodiment. As shown in FIG. 3, the method for testing a nonlinear parameter of a motor according to this embodiment includes the following steps.

At step 31, the motor is driven to vibrate by an excitation signal.

At step 32, synchronous information acquisition is performed on the vibrating motor to obtain a measured voltage value and a measured current value.

At step 33, an initial value of a linear parameter and an initial value of a nonlinear parameter of the motor are acquired.

At step 34, a target value of the linear parameter of the motor is calculated according to the measured voltage value, the measured current value and the initial value of the linear parameter.

Steps 31-34 respectively correspond to steps 11-14 in the first embodiment. For details of steps 31-34, refer to the corresponding description of steps 11-14 in the first embodiment. Therefore, detailed explanations of steps 31-34 are not repeated herein. Steps 35-38 involve a possible implementation mode of step 15 in the first embodiment, which is described as follows in detail.

At step 35, a system initial value which affects the nonlinear parameter is acquired.

The system characteristics of the nonlinear model and linear model of the motor remain unchanged, and only the nonlinear parameter is added. Referring to the description of sub-step S141 for testing the linear parameter in step 14 in the first embodiment, an electric equation of the nonlinear parameters of the motor is established to obtain a formula (7):

$${u}_{e} = {R}_{e} i + \frac{d ( {L}_{e} ( x ) i )}{d t} + B l ( x ) \frac{d x}{d t} . \qquad ( 7 )$$

A mechanical equation of the nonlinear parameters of the linear resonance actuator is established to obtain a formula (8):

$$B l ( x ) i = m \frac{{d}^{2} x}{d {t}^{2}} + {R}_{m s} ( x ) \frac{d x}{d t} + {k}_{m s} ( x ) x - {L}_{e} ( x ) \frac{{i}^{2}}{2} . \qquad ( 8 )$$

In the formulas (7) and (8), uₑ is the voltage across the two ends of the motor; Rₑ is the impedance of the voice coil of the motor; i is the current through the two ends of the motor; Lₑ(x) is the inductance of the voice coil; Bl(x) is the magnetic force coefficient; m is the mass of the vibrator of the motor; Rₘₛ(x) is the mechanical damping of a damper; kₘₛ(x) is the suspension stiffness coefficient of a spring; x is the displacement of the vibrator of the motor; and t is time. The electromagnetic force coefficient Bl(x), the inductance Lₑ(x) of the voice coil, the mechanical damping Rₘₛ(x) of the damper and the stiffness coefficient kₘₛ(x) of the spring are the nonlinear parameters tested in this embodiment.

The required precision of the nonlinear parameters, including the inductance Lₑ(x) of the voice coil, the electromagnetic force coefficient Bl(x), the mechanical damping Rₘₛ(x) of the damper and the stiffness coefficient kₘₛ(x) of the spring are determined according to needs to establish the formula for calculating the nonlinear parameters. In this embodiment, four-order precision is adopted as an example to obtain a formula (9) for the electromagnetic force coefficient Bl(x), a formula (10) for the inductance of the voice coil Lₑ(x), a formula (11) for the mechanical damping of the damper Rₘₛ(x), and a formula (12) for the stiffness coefficient of the spring kₘₛ(x):

Bl(x)=Bl₀+Bl₁x+Bl₂x²+Bl₃x³+Bl₄x⁴ (9)

Lₑ(x)=L₀+L₁x+L₂x²+L₃x³+L₄x⁴ (10)

Kₘₛ(x)=K₀+K₁x+K₂x²+K₃x³+K₄x⁴ (11)

Rₘₛ(x)=R₀+R₁x+R₂x²+R₃x³+R₄x⁴ (12).

In formulas (9)-(12), Bl₀, L₀, K₀ and R₀ are the target values of the linear parameters obtained in step 34. Acquiring the system initial values which affect the nonlinear parameters is to acquire the initial values of Bl₁ to Bl₄, L₁ to L₄, K₁ to K₄, and R₁ to R₄ in formulas (9)-(12). Those initial values can be obtained with a method preset by the user.

At step 36. an update value of the nonlinear parameter is calculated according to the measured voltage value, the measured current value, the target value of the linear parameter, the initial value of the nonlinear parameter and the system initial value.

The measured voltage value, the measured current value, the target value of the linear parameter, the initial value of the nonlinear parameter and the system initial value are substituted into the formulas (9)-(12) to solve for the update value of each of the nonlinear parameters, respectively. The following are specific steps.

At step S361, a displacement of a vibrator of the motor is calculated according to the measured voltage value, the measured current value and the initial value of the linear parameter.

Formulas (7) and (8) are modified into the format of state space to obtain the formula for calculating the displacement x. The obtained formula is related to measurements of the voltage value and the current value, and the nonlinear parameters including the electromagnetic force coefficient, the inductance of the voice coil, the mechanical damping of the damper and the stiffness coefficient of the spring. Accordingly, the displacement x of the vibrator of the motor is calculated according to the measured voltage value, the measured current value, the initial value of the electromagnetic force coefficient, the initial value of the inductance of the voice coil, the initial value of the mechanical damping of the damper and the initial value of the stiffness coefficient of the spring.

At step S362, an update value of the nonlinear parameter is calculated according to the target value of the linear parameter, the displacement of the vibrator of the motor, and the system initial value.

The displacement x of the vibrator of the motor obtained in step S361, the target values of the linear parameters Bl₀, L₀, K₀ and R₀ obtained in step 34, and the system initial values Bl₁ to Bl₄, L₁ to L₄, K₁ to K₄, and R₁ to R₄ obtained in step S35 are substituted into formulas (9)-(12) to solve for the update values of the nonlinear parameters.

At step S37, a difference between the update value of the nonlinear parameter and the initial value of the nonlinear parameter is calculated, and when the difference is less than a pre-determined threshold value, the update value of the nonlinear parameter is determined as the target value of the nonlinear parameter.

It is judged whether or not the update values of the nonlinear parameters meet the required precision according to the update values and initial values of the nonlinear parameters. Specifically, each of the initial values of the nonlinear parameters is deducted by a corresponding one of the update values of the nonlinear parameters to obtain a difference; the difference is compared with a corresponding pre-set threshold value; if the difference is smaller than the pre-set threshold value, the precision requirement is met, and the update value of the nonlinear parameter is used as the target value of the nonlinear parameter. Measurement of the nonlinear parameter of the motor allows for accurate control of the vibration of the motor using a nonlinear model, which enhances the accuracy of the motor control. Therefore, the method disclosed herein improves the performance of the motor, and solves the problem in the related art that large errors generated during nonlinear modeling of the motor result in low accuracy of motor control and failure to achieve the desired effects.

In this embodiment, the pre-set threshold values are fixed values preset by the user according to the desired precision.

At Step 38, when the difference is not smaller than the pre-determined threshold value, the system update value is calculated according to the measured voltage value, the measured current value, the target value of the linear parameter, the update value of the nonlinear parameter and the system initial value, the system update value is set as the system initial value and the update value of the nonlinear parameter is set as the initial value of the nonlinear parameter, and the method returns back to the step of calculating the update value of the nonlinear parameter according to the measured voltage value, the measured current value, the target value of the linear parameter, the initial value of the nonlinear parameter and the system initial value.

When the difference is not smaller than the preset threshold value, this means that the update value of the current nonlinear parameter does not meet the precision requirement. Then, the update value of the current nonlinear parameter is determined as the initial value of the nonlinear parameter for continuing calculation. The continuing calculation includes the following specific steps.

At step S381, an error value is calculated according to the measured voltage value, the measured current value, the target value of the linear parameter and the update value of the nonlinear parameter.

In this embodiment, the least mean square (LMS) adaptive filter is used as an example. An error function of the LMS is derived according to the electric equation (7) and the mechanical equation (8) of the nonlinear system of the motor, and the error value is calculated using the error function, as follows.

At step S3811, the measured voltage value, the measured current value and the initial value of the linear parameter are substituted into the electric equation for the vibration of the motor to solve for a first speed.

A formula (13) for the first speed v1 is obtained according to the electric equation (7):

$$\frac{d x}{d t} \vert u = \frac{1}{B l ( x )} ( {u}_{e} ( t ) - {R}_{e} i - \frac{d ( {L}_{e} ( x ) i )}{d t} ) \qquad ( 13 )$$

The measured voltage value uₑ(t), the measured current value i and the initial values of the linear parameters are substituted into formula (13) to obtain the first speed value.

At step S3812, the measured voltage value, the measured current value, the target value of the linear parameter and the initial value of the nonlinear parameter are substituted into a mechanical equation for the vibration of the motor to solve for a second speed.

A formula (14) for the second speed v2 is obtained according to the mechanical equation (8):

$$\frac{d x}{d t} \vert F = {L}^{- 1} \{ \frac{s}{J ( s )} \} * [ B l ( x ) i - ( {K}_{m s} ( x ) - {K}_{0} ) x - ( {R}_{m s} ( x ) - {R}_{0} ) ν + \frac{{i}^{2}}{2} \frac{d L e ( x )}{d x} ] \qquad ( 14 )$$

In this formula, J(s)=ms²+R₀s+K₀ and L⁻¹{ } represents inverse Laplace transform.

The measured voltage value uₑ(t), the measured current value i, the target values R₀ and K₀ of the linear parameters, and the initial values of the linear parameters are substituted into formula (14) to obtain the second speed value.

At step S3813, an error value is calculated according to the first speed and the second speed.

A difference between the formula (13) for the first speed and the formula (14) for the second speed is calculated to obtain an error function, as shown in formula (15):

$$e = \frac{d x}{d t} \vert u - \frac{d x}{d t} \vert F . \qquad ( 15 )$$

The first speed and the second speed are substituted into the formula (15) to obtain the error value.

At step S382, the system update value is calculated according to the error value and the system initial value.

After the error value of the LMS is obtained, the system initial value is updated according to the error value. The established updated formulas (16), (17), (18) and (19) are as follows:

$$\begin{matrix}{Bl}_{j}^{′} = B {l}_{j} - μ e \frac{\partial e}{\partial {Bl}_{j}} & ( 16 ) \\ {L}_{j}^{′} = {L}_{j} - μ e \frac{\partial e}{\partial {L}_{j}} & ( 17 ) \\ {K}_{j}^{′} = {K}_{j} - μ e \frac{\partial e}{\partial {K}_{j}} & ( 18 ) \\ {R}_{j}^{′} = {R}_{j} - μ e \frac{\partial e}{\partial {R}_{j}} . & ( 19 )\end{matrix}$$

In the formulas, Blⱼ′, Lⱼ′, Kⱼ′ and Rⱼ′ are updated system update values; j=1, 2, 3, 4; and μ is an iteration step size of the LMS. The specific value of the iteration step size can be preset by the user.

At step S383, the system update value is set as the system initial value and the update value of the nonlinear parameter is set as the initial value of the nonlinear parameter, and method returns back to the step of calculating the update value of the nonlinear parameter according to the measured voltage value, the measured current value, the target value of the linear parameter, the initial value of the nonlinear parameter and the system initial value.

The current update value obtained by calculation is used to update the initial value for next calculation, and the steps 36-38 are implemented again until the target value of the nonlinear parameter is obtained.

This embodiment provides the method for testing the nonlinear parameter of the motor. The method includes the following steps of exciting the motor to vibrate by an excitation signal; performing synchronous information acquisition on the vibrating motor to obtain the measured voltage value and the measured current value; acquiring the initial value of the linear parameter and the initial value of the nonlinear parameter of the motor; calculating the target value of the linear parameter of the motor according to the measured voltage value, the measured current value and the initial value of the linear parameter; acquiring the system initial value which affects the nonlinear parameter; calculating the update value of the nonlinear parameter according to the measured voltage value, the measured current value, the target value of the linear parameter, the initial value of the nonlinear parameter and the system initial value; calculating the difference between the update value of the nonlinear parameter and the initial value of the nonlinear parameter, and when the difference is less than the pre-determined threshold value, setting the update value of the nonlinear parameter as the target value of the nonlinear parameter; when the difference is not smaller than the pre-determined threshold value, calculating the system update value according to the measured voltage value, the measured current value, the target value of the linear parameter, the update value of the nonlinear parameter and the system initial value, setting the system update value as the system initial value and the update value of the nonlinear parameter as the initial value of the nonlinear parameter, and returning back to the step of calculating the update value of the nonlinear parameter according to the measured voltage value, the measured current value, the target value of the linear parameter, the initial value of the nonlinear parameter and the system initial value, thus obtaining the target value of the nonlinear parameter of the linear resonance actuator. Measurement of the nonlinear parameter of the linear resonance actuator allows for accurate control of the vibration of the motor using the nonlinear model, and enhances precision of the motor control. Therefore, the method disclosed herein improves the performance of the linear resonance actuator, and solves the problem in the related art that large errors generated during nonlinear modeling of the motor can result in low precision of the motor control and failure to achieve the desired effects.

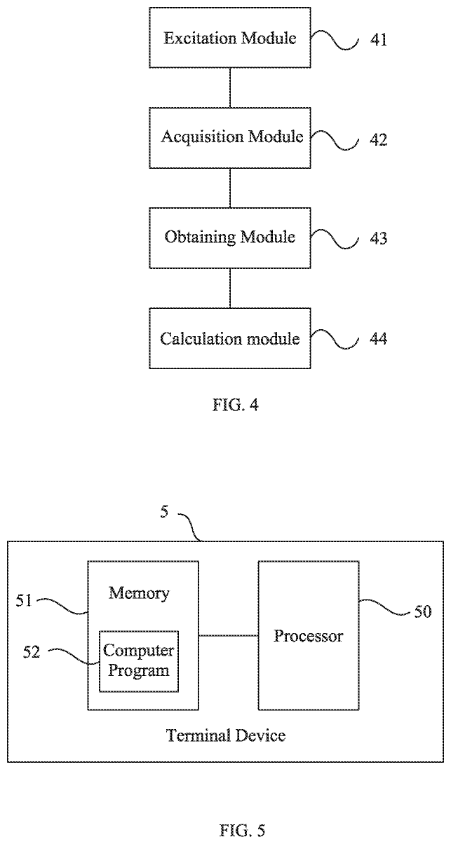

FIG. 4 is a schematic view illustrating an apparatus for testing a nonlinear parameter of a motor according to a third embodiment of the present disclosure. As shown in FIG. 4, the apparatus for testing the nonlinear parameter of the linear resonance actuator according to this embodiment includes an excitation module 41, an acquisition module 42, an obtaining module 43, and a calculation module 44.

The excitation module 41 is configured to drive the motor to vibrate by an excitation signal.

The acquisition module 42 is configured to perform synchronous information acquisition on the vibrating motor to obtain a measured voltage value and a measured current value.

The obtaining module 43 is configured to acquire an initial value of a linear parameter and an initial value of a nonlinear parameter of the motor.

The calculation module 44 is configured to calculate a target value of the linear parameter of the motor according to the measured voltage value, the measured current value and the initial value of the linear parameter;

The calculation module 44 is also configured to perform adaptive filtering calculation according to the measured voltage value, the measured current value, the target value of the linear parameter and the initial value of the nonlinear parameter to obtain a target value of the nonlinear parameter of the motor.

The apparatus for testing the nonlinear parameter of the motor provided in this embodiment is used to implement the method for testing the nonlinear parameter of the linear resonance actuator provided in the first embodiment. For details of the functions of the modules, refer to the corresponding description in the method embodiments. Since the principles and technical effects are similar, the modules are not described in further detail herein.

FIG. 5 is a schematic view showing a terminal device according to a fourth embodiment of the present disclosure. As shown in FIG. 5, the terminal device 5 in this embodiment includes at least one processor 50, a memory 51 in communication with the at least one processor 50, and a computer program 52 which is stored on the memory 51 and can be executed by the at least one processor 50. The computer program 52 is, for example, a program for testing the nonlinear parameter of the motor. The processor 50, when running the computer program 52, implements the steps of the method for testing the nonlinear parameter of the linear resonance actuator in each of the embodiments, for example the steps 11-15 as shown in FIG. 1. In addition or alternatively, the processor 50, when running the computer program 52, performs the functions of the modules in the apparatus embodiment described above, for example, the functions of modules 41-44 as shown in FIG. 4.

Just as an example, the computer program 52 can be divided into one or more modules/units, and the one or more modules/units are stored in the memory 51 and implemented by the processor 50 to realize the method disclosed herein. The one or more modules/units can be a series of computer program instruction segments capable of completing specific functions. The instruction segments are used to describe the implementation process of the computer program 52 in the terminal device 5. For example, the computer program 52 can be divided into an excitation module, an acquisition module, an obtaining module and a calculation module (unit modules in a virtual device), and the specific functions of each module are as follows.

The excitation module is used for exciting a motor to vibrate by an excitation signal.

The acquisition module is used for performing synchronous information acquisition on the vibrating motor to obtain a measured voltage value and a measured current value.

The obtaining module is used for acquiring an initial value of a linear parameter and an initial value of a nonlinear parameter of the motor.

The calculation module is used for calculating a target value of the linear parameter of the motor according to the measured voltage value, the measured current value and the initial value of the linear parameter.

The calculation module also performs adaptive filtering calculation according to the measured voltage value, the measured current value, the target value of the linear parameter and the initial value of the nonlinear parameter to obtain a target value of the nonlinear parameter of the motor.

The terminal device 5 can be a computing device such as a desktop computer, a notebook, a palm computer, or a cloud server. The terminal device 5 can include, among others, the processor 50 and the memory 51. Those skilled in the art can understand that the terminal device shown FIG. 5 is illustrative rather than restrictive. The terminal device can include more or less parts than those in the figure, or a combination of some parts, or have different parts. For example, the terminal device 5 can also include some input and output units, network access units, buses, etc.

The processor 50 can be a central processing unit (CPU), or another type of general processor, a digital signal processor (DSP), an application specific integrated circuit (ASIC), a field-programmable gate array (FPGA) or another programmable logistic unit, a discrete-gate or transistor logistic unit, a discrete hardware component, etc. The general processor can be a micro-processor or any conventional processor.

The memory 51 can be an internal storage unit of the terminal device 5, for example a hard disk drive or an internal memory of the terminal device 5. The memory 51 can also be an external storage unit of the terminal device 5, for example, a plug-in hard disk attached to the terminal device 5, a smart media card (SMC), a secure digital (SD) card, a flash card, etc. Further, the memory 51 can also include both the internal storage unit of the terminal device 5 and the external storage device. The memory 51 is used to store the computer program and other programs and data required by the terminal device 5. The memory 51 can also be used to temporarily store data that has been outputted or is to be outputted.

Those skilled in the art can clearly appreciate that, for convenient description and concision, the division of the functional units and modules described above are used for illustration only. In actual application, the functions mentioned above can be allocated to and conducted by different functional units and modules according to needs, meaning that the internal functional structure of the terminal device can be divided into different functional units and modules to conduct all or part of the functions described above. In these embodiments, various functional units and modules can be integrated into one processing unit, or individually and physically exist as individual units. Alternatively, two or more units can be integrated into one unit. The integrated units can be realized in not only hardware form, but also software form. In addition, the specific names of various functional units and modules are given for distinguishing purpose only, and shall not be regarded as restrictive. The specific working process of the system units and modules described above can be understood by referring to the corresponding processes of the method embodiments described above, and therefore is not described in detail herein.

In the above embodiments, the descriptions of each embodiment have their own emphasis. For those parts that are not detailed or described in a certain embodiment, please refer to the relevant descriptions of other embodiments.

Those skilled in the art can be aware of that the units and method steps of the examples described in conjunction with the embodiments can be performed by electronic hardware or a combination of computer software and electronic hardware. Whether the functions are conducted by hardware or software depends on the specific application and design restriction conditions of the technical solution. Those skilled in the art may adopt different methods to realize the described functions in specific applications, but such realization process shall not be regarded as going beyond the scope of the present disclosure.

It should be understood that the apparatuses/terminal devices and methods disclosed in the embodiments of the present disclosure can also be realized in other ways. For example, the embodiments of the apparatus/terminal device are merely illustrative. For instance, the division of the modules or units as described herein is merely an exemplary division of logical functions. Various other division methods can be adopted in actual application, for example, a plurality of units or components can be combined or integrated in another system, or some features can be omitted and are not implemented. Moreover, all illustrated or discussed indirect coupling, direct coupling or communication connection can be achieved by some interfaces, and the indirect coupling or communication connection can be electrical, mechanical or in other form.

The units described as separate parts can be or be not physically separate; the parts illustrated as units can be or be not physical units, i.e. they can be located at one place or distributed among a plurality of network units. Some or all of the units can be selected according to needs to achieve the objectives of the solutions of the embodiments.

In addition, in the embodiments of the present disclosure, various functional units can be integrated into one processing unit, or individually and physically exist as individual units; or two or more units are integrated into one unit. The integrated units can be achieved in not only hardware form, but also in software form.

If implemented in the form of software and sold and used as an independent product, the integrated modules/units can be stored on a computer-readable medium. Based on such understanding, all or some of the steps of the methods in the embodiments of the present disclosure can be implemented by hardware instructed by the computer program. The computer program can be stored on a computer-readable storage medium. The processor, which executing the computer program, can implement the steps of all methods disclosed in the embodiments. The computer program includes computer program codes that may be in the form of source codes, object codes, executable files or some intermediate codes. The computer-readable medium can include any physical device or apparatus capable of carrying the computer program codes, recording medium, USB flash disks, mobile hard disks, magnetic disks, optical disks, computer memories, read-only memory (ROM), random access memory (RAM), electric carrier signals, telecommunication signals, software distribution medium, etc.

It should be understood that the sequence numbers of the steps in the embodiments described above does not decide the implementation sequence, and the implementation sequence of each method depends on the functions and internal logic. Therefore, the sequence numbers of the steps shall not be construed as any limit to the implementation process of the embodiments of the present disclosure.

The features of the above embodiments can be combined in any suitable manner. For concise description, it is impossible to describe all possible combinations of the features of the above embodiments. However, as long as there is no contradiction in a combination of features of the present disclosure, that combination shall be considered as falling within the protective scope of the present disclosure.

Although the disclosure is described with reference to one or more embodiments, it will be apparent to those skilled in the art that various modifications and variations can be made to the disclosed structure and method without departing from the scope or spirit of the disclosure. In view of the foregoing, it is intended that the present disclosure cover modifications and variations of this invention provided they fall within the scope of the following claims and their equivalents.

1. A method for testing a nonlinear parameter of a motor, comprising:
exciting the motor to vibrate by an excitation signal;
performing synchronous information acquisition on the vibrating motor to obtain a measured voltage value and a measured current value;
acquiring an initial value of a linear parameter and an initial value of a nonlinear parameter of the motor;
calculating a target value of the linear parameter of the motor according to the measured voltage value, the measured current value and the initial value of the linear parameter;
performing adaptive filtering calculation according to the measured voltage value, the measured current value, the target value of the linear parameter and the initial value of the nonlinear parameter to obtain a target value of the nonlinear parameter of the motor.

2. The method for testing a nonlinear parameter of a motor according to claim 1, wherein the step of performing the adaptive filtering calculation comprises:
acquiring a system initial value which affects the nonlinear parameter;
calculating an update value of the nonlinear parameter according to the measured voltage value, the measured current value, the target value of the linear parameter, the initial value of the nonlinear parameter and the system initial value;
calculating a difference between the update value of the nonlinear parameter and the initial value of the nonlinear parameter, and when the difference is smaller than a predetermined threshold value, setting the update value of the nonlinear parameter as the target value of the nonlinear parameter;
when the difference is not smaller than the predetermined threshold value, calculating a system update value according to the measured voltage value, the measured current value, the target value of the linear parameter, the update value of the nonlinear parameter and the system initial value, setting the system update value as the system initial value and the update value of the nonlinear parameter as the initial value of the nonlinear parameter, and returning back to the step of calculating the update value of the nonlinear parameter according to the measured voltage value, the measured current value, the target value of the linear parameter, the initial value of the nonlinear parameter and the system initial value.

3. The method for testing a nonlinear parameter of a motor according to claim 2, wherein the step of calculating the update value of the nonlinear parameter according to the measured voltage value, the measured current value, the target value of the linear parameter, the initial value of the nonlinear parameter and the system initial value comprises:
calculating a displacement of a vibrator of the motor according to the measured voltage value, the measured current value and the initial value of the linear parameter; and
calculating the update value of the nonlinear parameter according to the target value of the linear parameter, the displacement of the vibrator of the motor and the system initial value.

4. The method for testing a nonlinear parameter of a motor according to claim 2, wherein the step of calculating the system update value according to the measured voltage value, the measured current value, the target value of the linear parameter, the update value of the nonlinear parameter and the system initial value comprises:
calculating an error value according to the measured voltage value, the measured current value, the target value of the linear parameter and the update value of the nonlinear parameter; and
calculating the system update value according to the error value and the system initial value.

5. The method for testing a nonlinear parameter of a motor according to claim 4, wherein the step of calculating the error value according to the measured voltage value, the measured current value, the target value of the linear parameter and the update value of the nonlinear parameter comprises:
substituting the measured voltage value, the measured current value and the initial value of the linear parameter into an electric equation for vibration of the motor to solve for a first speed;
substituting the measured voltage value, the measured current value, the target value of the linear parameter and the initial value of the nonlinear parameter into a mechanical equation for vibration of the motor to solve for a second speed; and
calculating the error value according to the first speed and the second speed.

6. The method for testing a nonlinear parameter of a motor according to claim 1, wherein the step of calculating the target value of the linear parameter of the motor according to the measured voltage value, the measured current value comprises:
deriving a voltage-to-current transfer function according to the electric equation and the mechanical equations for the motor;
substituting the measured voltage value and the initial value of the linear parameter into the transfer function to solve for a calculated current value; and
performing data fitting on the measured current value and the calculated current value to obtain the target value of the linear parameter.

7. The method for testing a nonlinear parameter of a motor according to claim 1, wherein the step of exciting the motor to vibrate by the excitation signal comprises:
generating the excitation signal;
performing filtering treatment on the excitation signal; and
exciting the motor to vibrate by the excitation signal after the filtering treatment.

8. An apparatus for testing a nonlinear parameter of a motor, comprising:
an excitation module configured for exciting the motor to vibrate by an excitation signal;
an acquisition module configured for performing synchronous information acquisition on the vibrating motor to obtain a measured voltage value and a measured current value;
an obtaining module configured for acquiring an initial value of a linear parameter and an initial value of a nonlinear parameter of the motor; and
a calculation module configured for calculating a target value of the linear parameter of the motor according to the measured voltage value, the measured current value and the initial value of the linear parameter,
the calculation module further configured for performing adaptive filtering calculation according to the measured voltage value, the measured current value, the target value of the linear parameter and the initial value of the nonlinear parameter to obtain a target value of the nonlinear parameter of the motor.

9. A terminal device comprising:
at least one processor;
a memory in communication with the at least one processor; and
a computer program stored on the memory, the computer program being executable by the at least one processor to implement a method for testing a nonlinear parameter of a motor, the method comprising:
exciting the motor to vibrate by an excitation signal;
performing synchronous information acquisition on the vibrating motor to obtain a measured voltage value and a measured current value;
acquiring an initial value of a linear parameter and an initial value of a nonlinear parameter of the motor;
calculating a target value of the linear parameter of the motor according to the measured voltage value, the measured current value and the initial value of the linear parameter; and
performing adaptive filtering calculation according to the measured voltage value, the measured current value, the target value of the linear parameter and the initial value of the nonlinear parameter to obtain a target value of the nonlinear parameter of the motor.

10. The terminal device according to claim 9, wherein the step of performing the adaptive filtering calculation comprises:
acquiring a system initial value which affects the nonlinear parameter;
calculating an update value of the nonlinear parameter according to the measured voltage value, the measured current value, the target value of the linear parameter, the initial value of the nonlinear parameter and the system initial value;
calculating a difference between the update value of the nonlinear parameter and the initial value of the nonlinear parameter, and when the difference is smaller than a predetermined threshold value, setting the update value of the nonlinear parameter as the target value of the nonlinear parameter;
when the difference is not smaller than the predetermined threshold value, calculating a system update value according to the measured voltage value, the measured current value, the target value of the linear parameter, the update value of the nonlinear parameter and the system initial value, setting the system update value as the system initial value and the update value of the nonlinear parameter as the initial value of the nonlinear parameter, and returning back to the step of calculating the update value of the nonlinear parameter according to the measured voltage value, the measured current value, the target value of the linear parameter, the initial value of the nonlinear parameter and the system initial value.

11. The terminal device according to claim 10, wherein the step of calculating the update value of the nonlinear parameter according to the measured voltage value, the measured current value, the target value of the linear parameter, the initial value of the nonlinear parameter and the system initial value comprises:
calculating a displacement of a vibrator of the motor according to the measured voltage value, the measured current value and the initial value of the linear parameter; and
calculating the update value of the nonlinear parameter according to the target value of the linear parameter, the displacement of the vibrator of the motor and the system initial value.

12. The terminal device according to claim 10, wherein the step of calculating the system update value according to the measured voltage value, the measured current value, the target value of the linear parameter, the update value of the nonlinear parameter and the system initial value comprises:
calculating an error value according to the measured voltage value, the measured current value, the target value of the linear parameter and the update value of the nonlinear parameter; and
calculating the system update value according to the error value and the system initial value.

13. The terminal device according to claim 12, wherein the step of calculating the error value according to the measured voltage value, the measured current value, the target value of the linear parameter and the update value of the nonlinear parameter comprises:
substituting the measured voltage value, the measured current value and the initial value of the linear parameter into an electric equation for vibration of the motor to solve for a first speed;
substituting the measured voltage value, the measured current value, the target value of the linear parameter and the initial value of the nonlinear parameter into a mechanical equation for vibration of the motor to solve for a second speed; and
calculating the error value according to the first speed and the second speed.

14. The terminal device according to claim 9, wherein the step of calculating the target value of the linear parameter of the motor according to the measured voltage value, the measured current value comprises:
deriving a voltage-to-current transfer function according to the electric equation and the mechanical equations for the motor;
substituting the measured voltage value and the initial value of the linear parameter into the transfer function to solve for a calculated current value; and
performing data fitting on the measured current value and the calculated current value to obtain the target value of the linear parameter.

15. A computer readable storage medium having a computer program stored thereon, the computer program being executable by a processor to implement a method for testing a nonlinear parameter of a motor as described in claim 1.

16. The computer readable storage medium according to claim 15, wherein the step of performing the adaptive filtering calculation comprises:
acquiring a system initial value which affects the nonlinear parameter;
calculating an update value of the nonlinear parameter according to the measured voltage value, the measured current value, the target value of the linear parameter, the initial value of the nonlinear parameter and the system initial value;
calculating a difference between the update value of the nonlinear parameter and the initial value of the nonlinear parameter, and when the difference is smaller than a predetermined threshold value, setting the update value of the nonlinear parameter as the target value of the nonlinear parameter;
when the difference is not smaller than the predetermined threshold value, calculating a system update value according to the measured voltage value, the measured current value, the target value of the linear parameter, the update value of the nonlinear parameter and the system initial value, setting the system update value as the system initial value and the update value of the nonlinear parameter as the initial value of the nonlinear parameter, and returning back to the step of calculating the update value of the nonlinear parameter according to the measured voltage value, the measured current value, the target value of the linear parameter, the initial value of the nonlinear parameter and the system initial value.

17. The computer readable storage medium according to claim 16, wherein the step of calculating the update value of the nonlinear parameter according to the measured voltage value, the measured current value, the target value of the linear parameter, the initial value of the nonlinear parameter and the system initial value comprises:
calculating a displacement of a vibrator of the motor according to the measured voltage value, the measured current value and the initial value of the linear parameter; and
calculating the update value of the nonlinear parameter according to the target value of the linear parameter, the displacement of the vibrator of the motor and the system initial value.

18. The computer readable storage medium according to claim 16, wherein the step of calculating the system update value according to the measured voltage value, the measured current value, the target value of the linear parameter, the update value of the nonlinear parameter and the system initial value comprises:
calculating an error value according to the measured voltage value, the measured current value, the target value of the linear parameter and the update value of the nonlinear parameter; and
calculating the system update value according to the error value and the system initial value.

19. The computer readable storage medium according to claim 18, wherein the step of calculating the error value according to the measured voltage value, the measured current value, the target value of the linear parameter and the update value of the nonlinear parameter comprises:
substituting the measured voltage value, the measured current value and the initial value of the linear parameter into an electric equation for vibration of the motor to solve for a first speed;
substituting the measured voltage value, the measured current value, the target value of the linear parameter and the initial value of the nonlinear parameter into a mechanical equation for vibration of the motor to solve for a second speed; and
calculating the error value according to the first speed and the second speed.

20. The computer readable storage medium according to claim 15, wherein the step of calculating the target value of the linear parameter of the motor according to the measured voltage value, the measured current value comprises:
deriving a voltage-to-current transfer function according to the electric equation and the mechanical equations for the motor;
substituting the measured voltage value and the initial value of the linear parameter into the transfer function to solve for a calculated current value; and
performing data fitting on the measured current value and the calculated current value to obtain the target value of the linear parameter.
